(19) United States
(12) Patent Application Publication
(10) Pub. No.: US 2024/0355788 A1
(43) Pub. Date: Oct. 24, 2024

(54) DISPLAY DEVICE

(71) Applicant: LG ELECTRONICS INC., Seoul (KR)

(72) Inventors: Sungmin PARK, Seoul (KR); Byoungkwon CHO, Seoul (KR); Wonseok CHOI, Seoul (KR)

(73) Assignee: LG ELECTRONICS INC., Seoul (KR)

(21) Appl. No.: 18/685,475

(22) PCT Filed: Aug. 26, 2021
(86) PCT No.: PCT/KR2021/011449

§ 371 Date: Feb. 21, 2024

(51) Int. Cl. H01L 25/075; H01L 33/22; H01L 33/44; H01L 33/62

(52) U.S. Cl. CPC H01L 25/0753; H01L 33/22; H01L 33/44; H01L 33/62

(57) ABSTRACT

A semiconductor light emitting device includes a light emitting part, a first electrode including a bonding layer below the light emitting part, a barrier around the bonding layer, a second electrode on the light emitting part, and a passivation layer to surround the light emitting part and the second electrode.

### TECHNICAL FIELD The embodiment relates to a display device.

### BACKGROUND ART

Display devices display high-definition images using self-luminous elements such as light emitting diodes as light sources for pixels. Light emitting diodes exhibit excellent durability even under harsh environmental conditions and are capable of long lifespan and high brightness, so they are attracting attention as a light source for next-generation display devices.

Recently, research is underway to manufacture ultra-small light emitting diodes using highly reliable inorganic crystal structure materials and place them on panels of display devices (hereinafter referred to as “display panels”) to use them as next-generation light sources.

These display devices are expanding beyond flat displays into various forms such as flexible displays, foldable displays, stretchable displays, and rollable displays.

In order to implement high resolution, the size of pixels is gradually becoming smaller, and light emitting devices must be aligned in numerous pixels of such smaller sizes, so that research on the manufacture of ultra-small light emitting diodes as small as micro or nano scale is being actively conducted.

Display devices typically contain tens of millions of pixels or more. Accordingly, because it is very difficult to align at least one light emitting device in each of tens of millions of small pixels, various studies on ways to align light emitting devices in a display panel are being actively conducted.

As the size of light emitting devices becomes smaller, quickly and accurately transferring these light emitting devices onto a substrate has become a very important problem to solve. Transfer technologies that have been recently developed include the pick and place process, laser lift-off method, or self-assembly method. In particular, a self-assembly method that transfers a light emitting device onto a substrate using a magnetic material (or magnet) has recently been in the spotlight.

In the self-assembly method, numerous light emitting devices are dropped into a bath containing a fluid, and as the magnetic material moves, the light emitting devices dropped into the fluid are moved to the pixels of the substrate, and the light emitting devices are aligned at each pixel. Therefore, the self-assembly method is attracting attention as a next-generation transfer method because it may quickly and accurately transfer numerous light emitting devices onto a substrate.

Meanwhile, light emitting devices assembled on a substrate by self-assembly method are electrically connected by heat compression method. That is, the bonding layer provided on the lower part of the light emitting device is melted by thermal compression and is electrically connected to the electrical wiring of the substrate.

However, there are the following problems when thermally compressing the bonding layer of a conventional light emitting device.

FIG. 1 shows the bonding material escaping around the light emitting device.

As shown in FIG. 1, when the light emitting device 4 is assembled into the assembly hole 3 and then heat-compressed, the bonding material 5 on the lower side of the light emitting device 4 is between the light emitting device 4 and the substrate 1. Rather than staying there, it escapes around the light emitting device 4. In this way, the bonding material 5 escapes around the light emitting device 4 and some of the bonding material 5 forms a sharp spire as high as the light emitting device 4. When electrode wiring (not shown) is placed on the upper side of the light emitting device 4 by a post-process, a problem occurs in which the upper and lower portions of the light emitting device 5 are electrically shorted due to the electrode wiring being in electrical contact with the bonding material 5.

FIG. 2 is a cross-sectional view showing a conventional light emitting device.

As shown in FIG. 2, a bonding material 5 is provided on the lower side of a conventional light emitting device. Conventionally, there is no structure provided to prevent the bonding material 5 from escaping in the side direction during heat compression.

Therefore, when the conventional light emitting device shown in FIG. 2 is thermo-compressed on the substrate 1 using a thermo-compression method as shown in FIG. 1, the bonding material 5 melted by the heat generated during the thermal compression process does not stay on the lower side of the light emitting device 4 but escapes to the surroundings of the light emitting device 4.

FIG. 3 shows the light emitting device being separated.

If the bonding material 5 previously escaped around the light emitting device 4, there was almost no bonding material 5 between the light emitting device 4 and the substrate 1, as shown in FIG. 3, the light emitting device 4 is not attached to the substrate 1 and is separated. That is, the light emitting device 5 is attached to the substrate 1 by the bonding material 5. In order for the light emitting device 5 to be strongly attached to the substrate 1, a certain bonding material 5 is to exist under the light emitting device 5 despite heat compression. However, during heat compression, most of the bonding material 5 provided on the lower side of the light emitting device 5 escapes around the light emitting device 5 and only a small amount of the bonding material 5 remains on the lower side of the light emitting device 5. Accordingly, the light emitting device 5 is not strongly attached to the substrate 1, and there is a problem that the light emitting device 5 is easily separated from the substrate 1. Deviation of the light emitting device 5 reduces the assembly rate and causes assembly defects or lighting defects.

FIG. 4 shows a poor electrical connection between the light emitting device and the electrical wiring of the substrate.

As shown in FIG. 4, when the bonding material 5 escapes to the periphery of the light emitting device 4 due to thermal compression, there is almost no bonding material 5 remaining on the lower side of the light emitting device 4 (see X area). That is, since the bonding material 5 does not exist continuously between the light emitting device 4 and the substrate 1, but exists locally, the electrical connection between the light emitting device 4 and the substrate 1 is also locally connected. This leads to an increase in electrical resistance between the light emitting device 4 and the substrate 1, which causes the electrical signal from the substrate 1 to not be easily supplied to the light emitting device 4, resulting in a decrease in luminance.

Meanwhile, during thermal compression, a press with a heater on the upper side of the light emitting device presses the light emitting device, and at this time, the heat of the heater melts the bonding material provided on the lower side of the light emitting device through the light emitting device. Usually, the heat from the heater is supplied more concentrated to the lower side of the light emitting device through the center of the light emitting device than to the surroundings of the light emitting device, the melting point between the bonding material corresponding to the center of the light emitting device and the bonding material corresponding to the periphery of the light emitting device varies. In other words, the melting point varies depending on the location of the bonding material, which becomes a factor limiting the smooth bonding process. That is, the bonding process time becomes longer or bonding defects occur.

### DISCLOSURE

### Technical Problem

The embodiment aims to solve the above-mentioned problems and other problems.

Another object of the embodiment is to provide a display device that may prevent bonding defects.

Another object of the embodiment is to provide a display device that may strengthen bonding force.

Another object of the embodiment is to provide a display device that may prevent assembly defects and lighting defects.

The technical objects of the embodiments are not limited to those described in this item and include those that may be understood through the description of the invention.

### Technical Solution

According to one aspect of the embodiment to achieve the above or other objects, a semiconductor light emitting device includes a light emitting part; a first electrode including a bonding layer below the light emitting part; a barrier around the bonding layer; a second electrode on the light emitting part and a passivation layer surrounding the light emitting part and the second electrode.

According to another aspect of the embodiment, the display device includes a substrate; first and second assembly lines on the substrate; a second insulating layer disposed on the substrate and having an assembly hole; a semiconductor light emitting device in the assembly hole. The semiconductor light emitting device includes a light emitting part; a first electrode including a bonding layer below the light emitting part; a barrier around the bonding layer; a second electrode on the light emitting part and a passivation layer surrounding the light emitting part and the second electrode. One of the first and second assembly wirings is electrically connected to the first electrode.

### Advantageous Effects

In the embodiment, as shown in FIGS. 11 to 13 and 19, a barrier 156 is disposed around the bonding layer 154_1 provided on the lower side of the semiconductor light emitting device 150, even if the bonding layer 154_1 is melted and pressed during thermal compression, the melted layer 154_1 does not escape to the periphery of the semiconductor light emitting device 150, that is, to the edge of the assembly hole 355, due to the barrier 156, or only a portion of it may escape.

Therefore, compared to the prior art, almost no bonding layer 154_1 escapes from the periphery of the semiconductor light emitting device 150, an electrical short circuit with the electrode wiring 360 caused by bonding material escaping around the semiconductor light emitting device 150 in the related art may be prevented.

In addition, there is almost no bonding layer 154_1 missing around the semiconductor light emitting device 150, most of the bonding layer 154_1 is located within the barrier 156, that is, between the semiconductor light emitting device 150 and the substrate 310, since the bonding layer 154_1 is provided with a predetermined thickness, for example, at least the thickness of the barrier 156 or a thickness greater than that of the barrier 156, it is possible to prevent electrical connection failure between the semiconductor light emitting device 150 and the lower electrode wiring, that is, the second assembly wiring 322.

In addition, there is almost no bonding layer 154_1 outside the periphery of the semiconductor light emitting device 150, and most of the bonding layer 154_1 is within the barrier 156, that is, since the bonding layer 154_1 is located between the semiconductor light emitting device 150 and the substrate 310 and is provided with a predetermined thickness, for example, at least the thickness of the barrier 156 or greater, the semiconductor light emitting device 150 is firmly attached to the substrate 310, for example, the first insulating layer 330 and the second assembly electrode, thereby preventing the semiconductor light emitting device 150 from being separated, thereby improving product reliability.

Meanwhile, the bonding layer 154_1 made of metal is disposed under the semiconductor light emitting device 150 with a thickness greater than the thickness of the barrier 156, which means that the volume or amount of the bonding layer 154_1 is increased. Typically, dielectrophoretic force is greatly affected by metallic materials. Therefore, the dielectrophoresis force increases due to the increased bonding layer 154_1, due to this increased dielectrophoretic force, the semiconductor light emitting device 150 is pulled more strongly into the assembly hole 355, thereby increasing the assembly rate and reducing assembly defects.

In addition, when the barrier 156 of the semiconductor light emitting device 150 disposed in each sub-pixel is the same during thermal compression, the bonding layer 154_1 melted by the thermal compression is confined by the barrier 156, the volume or amount of the bonding layer 154_1 remaining between the semiconductor light emitting device 150 and the substrate 310 in each sub-pixel may be the same or similar. Accordingly, since the light output by the same voltage in each sub-pixel is the same or similar, the luminance in each sub-pixel is also the same or similar, so that uniform luminance may be achieved.

In addition, during thermal compression, heat is not only transferred to the upper side of the bonding layer (154_1) through the central area of the light emitting portions (151, 152, and 153), but also transferred to the side of the bonding layer 154_1 through the barrier 156 located corresponding to the edge area of the light emitting portions 151, 152, and 153, since the entire area of the bonding layer 154_1 may be melted at the same time, a smooth bonding process may be performed. In other words, bonding may be completed at the same time, shortening the bonding process time, and bonding defects due to different melting times may be prevented.

In the embodiment, as shown in FIG. 20, a portion of the first conductivity type semiconductor layer containing the first conductivity type dopant, that is, the edge region, may be formed as a barrier, and the bonding layer may be surrounded by this barrier.

Since the barrier is conductive and heat is transmitted to the bonding layer through the barrier during heat compression, heat is evenly transmitted to all areas of the bonding layer, allowing a smooth bonding process to be performed. Accordingly, bonding may be completed at the same time, shortening the bonding process time, and bonding defects due to different melting times may be prevented.

In the embodiment, as shown in FIGS. 21 and 22, when the barrier is formed, the unevenness is formed on the lower side of the light emitting part, since there is no need to form separate unevenness, the structure is simple, the process time is shortened, and the manufacturing cost may be reduced.

Additional scope of applicability of the embodiments will become apparent from the detailed description below. However, since various changes and modifications within the spirit and scope of the embodiments may be clearly understood by those skilled in the art, the detailed description and specific embodiments, such as preferred embodiments, should be understood as being given by way of example only.

### DESCRIPTION OF DRAWINGS

FIG. 1 shows the bonding material escaping around the light emitting device.

FIG. 2 is a cross-sectional view showing a conventional light emitting device.

FIG. 3 shows the light emitting device being separated.

FIG. 4 shows a poor electrical connection between the light emitting device and the electrical wiring of the substrate.

FIG. 5 shows a living room of a house where a display device according to an embodiment is placed.

FIG. 6 is a block diagram schematically showing a display device according to an embodiment.

FIG. 7 is a circuit diagram showing an example of the pixel of FIG. 6.

FIG. 8 is an enlarged view of the first panel area in the display device of FIG. 5.

FIG. 9 is an enlarged view of area A2 in FIG. 8.

FIG. 10 is a diagram showing an example in which a light emitting device according to an embodiment is assembled on a substrate by a self-assembly method.

FIG. 11 is a cross-sectional view showing a display device according to an embodiment.

FIG. 12 is a cross-sectional view showing a semiconductor light emitting device according to the first embodiment.

FIG. 13 is a bottom view showing a semiconductor light emitting device according to an embodiment.

FIGS. 14 to 16 show a method of manufacturing a semiconductor light emitting device according to an embodiment.

FIGS. 17A and 17B are photographic images showing bonding layers of the prior art and embodiments.

FIGS. 18A and 18B show lighting situations in display devices of the related art and embodiments.

FIG. 19 is a cross-sectional view showing a semiconductor light emitting device according to the second embodiment.

FIG. 20 is a cross-sectional view showing a semiconductor light emitting device according to the third embodiment.

FIG. 21 is a cross-sectional view showing a semiconductor light emitting device according to the fourth embodiment.

FIG. 22 is a cross-sectional view showing a semiconductor light emitting device according to the fifth embodiment.

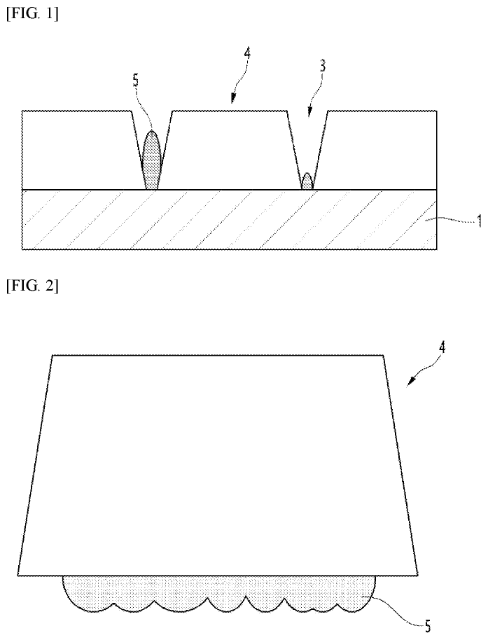

The size, shape, and dimensions of the components shown in the drawings may differ from the actual ones. In addition, although the same components are shown in different sizes, shapes, and numbers between drawings, this is only an example in the drawings, identical components may have the same size, shape, and numerical value between drawings.

### MODE FOR INVENTION

Hereinafter, embodiments disclosed in the present specification will be described in detail with reference to the attached drawings, but identical or similar components will be assigned the same reference numbers regardless of the reference numerals, and duplicate descriptions thereof will be omitted. The suffixes ‘module’ and ‘part’ for components used in the following description are given or used interchangeably in consideration of ease of specification preparation, and do not have distinct meanings or roles in themselves. Additionally, the attached drawings are intended to facilitate easy understanding of the embodiments disclosed in this specification, and the technical idea disclosed in this specification is not limited by the attached drawings. Additionally, when an element such as a layer, region or substrate is referred to as being ‘on’ another component, this includes either directly on the other element or there may be other intermediate elements in between.

Display devices described in this specification include TVs, shines, mobile phones, smart phones, head-up displays (HUDs) for automobiles, backlight units for laptop computers, displays for VR or AR, etc. However, the configuration according to the embodiment described in this specification may be applied to a device capable of displaying even if it is a new product type that is developed in the future.

Hereinafter, a light emitting device according to an embodiment and a display device including the same will be described.

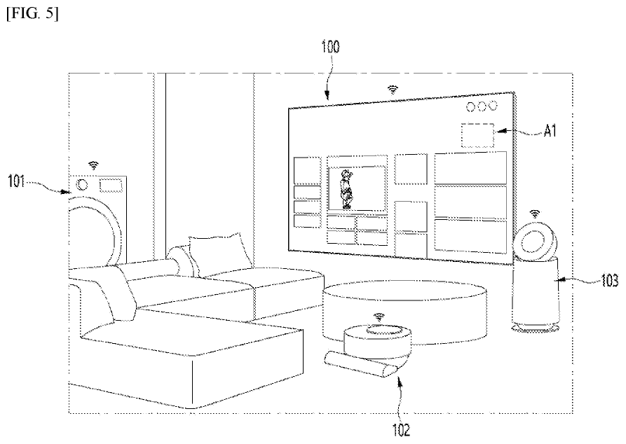

FIG. 5 shows a living room of a house where a display device according to an embodiment is placed.

Referring to FIG. 5, the display device 100 of the embodiment may display the status of various electronic products such as a washing machine 101, a robot vacuum cleaner 102, and an air purifier 103, may communicate with each electronic product based on IOT and may also control each electronic product based on the user's setting data.

The display device 100 according to the embodiment may include a flexible display manufactured on a thin and flexible substrate. Flexible displays may bend or curl like paper while maintaining the characteristics of existing flat displays.

In a flexible display, visual information may be implemented by independently controlling the light emission of unit pixels arranged in a matrix form. A unit pixel refers to the minimum unit for implementing one color. A unit pixel of a flexible display may be implemented by a light emitting device. In the embodiment, the light emitting device may be Micro-LED or Nano-LED, but is not limited thereto.

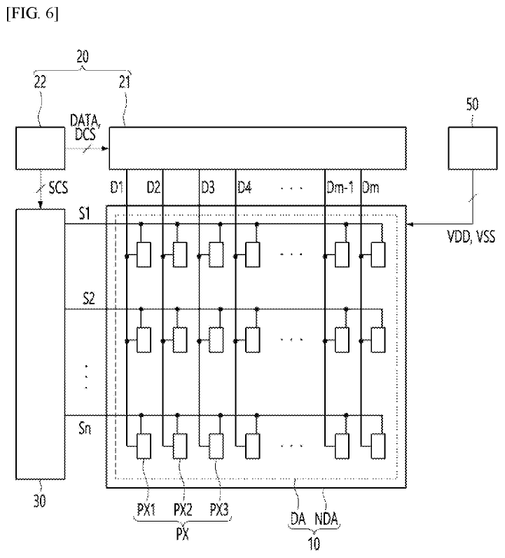

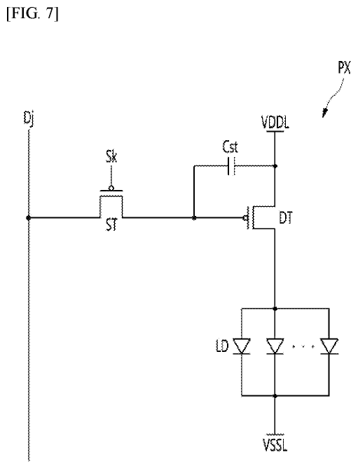

FIG. 6 is a block diagram schematically showing a display device according to an embodiment, and FIG. 7 is a circuit diagram showing an example of the pixel of FIG. 6.

Referring to FIGS. 6 and 7, a display device according to an embodiment may include a display panel 10, a driving circuit 20, a scan driver 30, and a power supply circuit 50.

The display device 100 of the embodiment may drive the light emitting device in an active matrix (AM, Active Matrix) method or a passive matrix (PM, Passive Matrix) method. The driving circuit 20 may include a data driver 21 and a timing control unit 22.

The display panel 10 may be rectangular, but this is not limited. That is, the display panel 10 may be formed in a circular or oval shape. At least one side of the display panel 10 may be bent to a predetermined curvature.

The display panel 10 may be divided into a display area DA and a non-display area NDA disposed around the display area DA. The display area DA is an area where pixels PX are formed to display an image. The display panel 10 may include data lines (D1 to Dm, m is an integer greater than 2), scan lines (S1 to Sn, n is an integer greater than 2) that intersect the data lines D1 to Dm, pixels PX connected to a high-potential voltage line to which a high-potential voltage is supplied, a low-potential voltage line to which a low-potential voltage is supplied, and data lines D1 to Dm and scan lines (S1 to Sn).

Each of the pixels PX may include a first sub-pixel PX1, a second sub-pixel PX2, and a third sub-pixel PX3. The first sub-pixel PX1 emits a first color light of a first main wavelength, the second sub-pixel PX2 may emit a second color light of a second main wavelength, and the third sub-pixel PX3 may emit a third color light of a third main wavelength. The first color light may be red light, the second color light may be green light, and the third color light may be blue light, but are not limited thereto. Additionally, in FIG. 6, it is illustrated that each pixel PX includes three sub-pixels, but the present invention is not limited thereto. That is, each pixel PX may include four or more sub-pixels.

Each of the first sub-pixel PX1, the second sub-pixel PX2, and the third sub-pixel PX3 may be connected to at least one of the data lines D1 to Dm and at least one of the scan lines S1 to Sn and a high potential voltage line. As shown in FIG. 7, the first sub-pixel PX1 may include light emitting devices LD, a plurality of transistors for supplying current to the light emitting devices LD, and at least one capacitor Cst.

Although not shown in the drawing, each of the first sub-pixel PX1, the second sub-pixel PX2, and the third sub-pixel PX3 may include only one light emitting device LD and at least one capacitor Cst.

Each of the light emitting devices LD may be a semiconductor light emitting diode including a first electrode, a plurality of conductivity type semiconductor layers, and a second electrode. Here, the first electrode may be an anode electrode and the second electrode may be a cathode electrode, but this is not limited.

The light emitting device LD may be one of a horizontal light emitting device, a flip chip type light emitting device, and a vertical light emitting device.

As shown in FIG. 7, the plurality of transistors may include a driving transistor DT that supplies current to the light emitting devices LD and a scan transistor ST that supplies a data voltage to the gate electrode of the driving transistor DT. The driving transistor DT may include a gate electrode connected to the source electrode of the scan transistor ST, a source electrode connected to a high-potential voltage line to which a high-potential voltage is applied and a drain electrode connected to the first electrodes of the light emitting devices (LD). The scan transistor ST may include a gate electrode connected to a scan line (Sk, k is an integer satisfying 1≤k≤n), a source electrode connected to the gate electrode of the driving transistor DT and a drain electrode connected to the data line (Dj, j is an integer satisfying 1≤j≤m).

The capacitor Cst is formed between the gate electrode and the source electrode of the driving transistor DT. The storage capacitor Cst charges the difference between the gate voltage and source voltage of the driving transistor DT.

The driving transistor DT and the scan transistor ST may be formed of a thin film transistor. In addition, in FIG. 7, the driving transistor DT and the scan transistor ST are explained with a focus on being formed of a P-type MOSFET (Metal Oxide Semiconductor Field Effect Transistor), but the present invention is not limited thereto. The driving transistor DT and scan transistor ST may be formed of an N-type MOSFET. In this case, the positions of the source and drain electrodes of the driving transistor DT and the scan transistor ST may be changed.

In addition, in FIG. 7, it is illustrated that each of the first sub-pixel PX1, the second sub-pixel PX2, and the third sub-pixel PX3 includes 2T1C (2 Transistor-1 capacitor) with one driving transistor DT, one scan transistor ST, and one capacitor Cst the present invention is not limited to this. Each of the first sub-pixel PX1, the second sub-pixel PX2, and the third sub-pixel PX3 may include a plurality of scan transistors ST and a plurality of capacitors Cst.

Since the second sub-pixel PX2 and the third sub-pixel PX3 may be represented by substantially the same circuit diagram as the first sub-pixel PX1, detailed descriptions thereof will be omitted.

The driving circuit 20 outputs signals and voltages for driving the display panel 10. For this purpose, the driving circuit 20 may include a data driver 21 and a timing controller 22.

The data driver 21 receives digital video data (DATA) and source control signal DCS from the timing control unit 22. The data driver 21 converts digital video data (DATA) into analog data voltages according to the source control signal (DCS) and supplies them to the data lines (D1 to Dm) of the display panel 10.

The timing control unit 22 receives digital video data (DATA) and timing signals from the host system. Timing signals may include a vertical sync signal, a horizontal sync signal, a data enable signal, and a dot clock. The host system may be an application processor in a smartphone or tablet PC, a monitor, or a system-on-chip in a TV.

The timing control unit 22 generates control signals to control the operation timing of the data driver 21 and the scan driver 30. The control signals may include a source control signal (DCS) for controlling the operation timing of the data driver 21 and a scan control signal (SCS) for controlling the operation timing of the scan driver 30.

The driving circuit 20 may be disposed in the non-display area (NDA) provided on one side of the display panel 10. The driving circuit 20 may be formed as an integrated circuit (IC) and mounted on the display panel 10 using a chip on glass (COG) method, a chip on plastic (COP) method, or an ultrasonic bonding method, but the present invention is not limited to this. For example, the driving circuit 20 may be mounted on a circuit board (not shown) rather than on the display panel 10.

The data driver 21 is mounted on the display panel 10 using a COG (chip on glass) method, a COP (chip on plastic) method, or an ultrasonic bonding method, and timing control unit 22 may be mounted on a circuit board.

The scan driver 30 receives a scan control signal (SCS) from the timing control unit 22. The scan driver 30 generates scan signals according to the scan control signal SCS and supplies them to the scan lines S1 to Sn of the display panel 10. The scan driver 30 may include a plurality of transistors and may be formed in the non-display area NDA of the display panel 10. Alternatively, the scan driver 30 may be formed as an integrated circuit, and in this case, it may be mounted on a gate flexible film attached to the other side of the display panel 10.

The circuit board may be attached to pads provided at one edge of the display panel 10 using an anisotropic conductive film. Because of this, the lead lines of the circuit board may be electrically connected to the pads. The circuit board may be a flexible printed circuit board, a printed circuit board, or a flexible film such as a chip on film. The circuit board may be bent toward the bottom of the display panel 10. Because of this, one side of the circuit board is attached to one edge of the display panel 10, and the other side is placed below the display panel 10 and may be connected to a system board on which the host system is mounted.

The power supply circuit 50 may generate voltages necessary for driving the display panel 10 from the main power supplied from the system board and supply them to the display panel 10. For example, the power supply circuit 50 generates a high potential voltage (VDD) and a low potential voltage (VSS) to drive the light emitting devices (LD) of the display panel 10 from the main power supply, so that may supply the high-potential voltage line and the low-potential voltage line of the display panel 10. Additionally, the power supply circuit 50 may generate and supply driving voltages for driving the driving circuit 20 and the scan driver 30 from the main power supply.

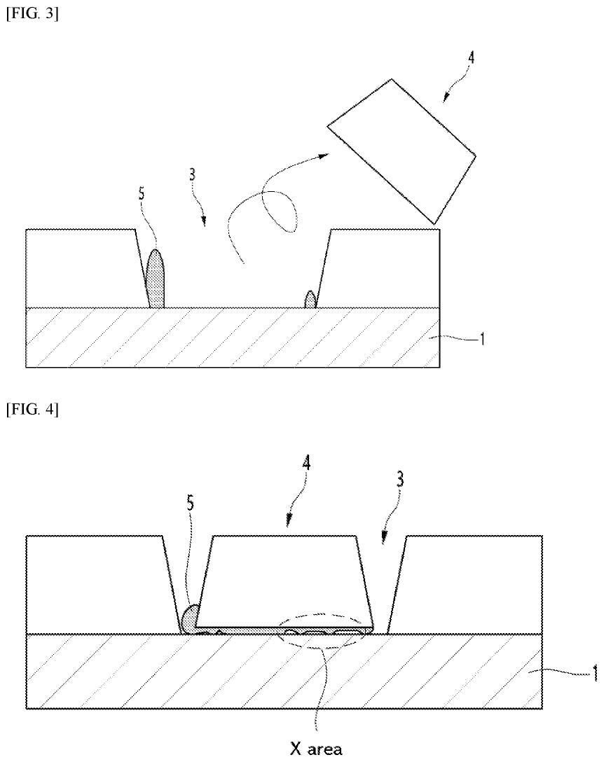

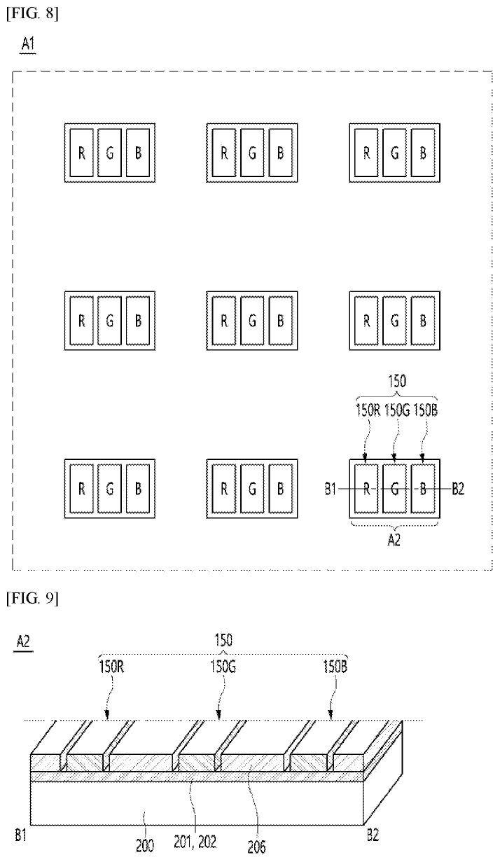

FIG. 8 is an enlarged view of the first panel area in the display device of FIG. 3.

Referring to FIG. 8, the display device 100 of the embodiment may be manufactured by mechanically and electrically connecting a plurality of panel areas, such as the first panel area A1, by tiling.

The first panel area A1 may include a plurality of light emitting devices 150 arranged for each unit pixel (PX in FIG. 6).

For example, the unit pixel PX may include a first sub-pixel PX1, a second sub-pixel PX2, and a third sub-pixel PX3. For example, a plurality of red light emitting devices 150R are disposed in the first sub-pixel PX1, a plurality of green light emitting devices 150G may be disposed in the second sub-pixel PX2, and a plurality of blue light emitting devices 150B may be disposed in the third sub-pixel PX3. The unit pixel PX may further include a fourth sub-pixel in which no light emitting device is disposed, but is not limited to this.

FIG. 9 is an enlarged view of area A2 in FIG. 8.

Referring to FIG. 9, the display device 100 of the embodiment may include a substrate 200, assembly wiring 201 and 202, an insulating layer 206, and a plurality of light emitting devices 150. More components may be included than this.

The assembly wiring may include a first assembly wiring 201 and a second assembly wiring 202 that are spaced apart from each other. The first assembly wiring 201 and the second assembly wiring 202 may be provided to generate dielectrophoretic force to assemble the light emitting device 150. For example, the light emitting device 150 may be one of a horizontal light emitting device, a flip chip type light emitting device, and a vertical light emitting device.

The light emitting device 150 may include, but is not limited to, a red light emitting device 150, a green light emitting device 150G, and a blue light emitting device 150BO to form a unit pixel (sub-pixel) and also possible to implement red and green colors by using red phosphors and green phosphors, respectively.

The substrate 200 may be a support member that supports components placed on the substrate 200 or a protection member that protects the components.

The substrate 200 may be a rigid substrate or a flexible substrate. The substrate 200 may be made of sapphire, glass, silicon, or polyimide. Additionally, the substrate 200 may include a flexible material such as PEN (Polyethylene Naphthalate) or PET (Polyethylene Terephthalate). Additionally, the substrate 200 may be made of a transparent material, but is not limited thereto.

The substrate 200 is a backplane equipped with circuits in the sub-pixels (PX1, PX2, PX3) shown in FIGS. 4 and 5, such as transistors (ST, DT), capacitors Cst, signal wires, etc., but is not limited to this.

The insulating layer 206 may include an insulating and flexible organic material such as polyimide, PAC, PEN, PET, polymer, etc., or an inorganic material such as silicon oxide (SiO2) or silicon nitride series (SiNx), and may be integrated with the substrate 200 to form one substrate.

The insulating layer 206 may be a conductive adhesive layer that has adhesiveness and conductivity, and the conductive adhesive layer may be flexible and enable a flexible function of the display device. For example, the insulating layer 206 may be an anisotropic conductive film (ACF) or a conductive adhesive layer such as an anisotropic conductive medium or a solution containing conductive particles. The conductive adhesive layer may be a layer that is electrically conductive in a direction perpendicular to the thickness, but electrically insulating in a direction horizontal to the thickness.

The insulating layer 206 may include an assembly hole 203 into which the light emitting device 150 is inserted. Therefore, during self-assembly, the light emitting device 150 may be easily inserted into the assembly hole 203 of the insulating layer 206. The assembly hole 203 may be called an insertion hole, a fixing hole, an alignment hole, etc.

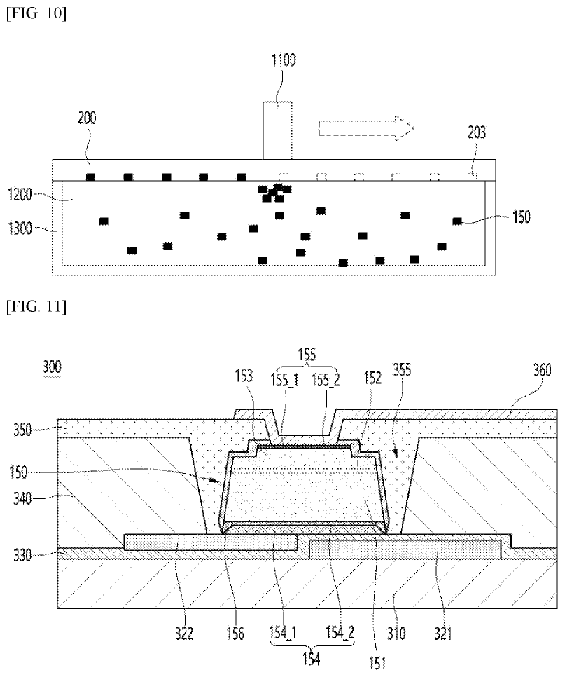

FIG. 10 is a diagram showing an example in which a light emitting device according to an embodiment is assembled on a substrate by a self-assembly method.

The self-assembly method of the light emitting device will be described with reference to FIGS. 9 and 10.

The substrate 200 may be a panel substrate of a display device. In the following description, the substrate 200 will be described as a panel substrate of a display device, but the embodiment is not limited thereto.

The substrate 200 may be formed of glass or polyimide. Additionally, the substrate 200 may include a flexible material such as PEN (Polyethylene Naphthalate) or PET (Polyethylene Terephthalate). Additionally, the substrate 200 may be made of a transparent material, but is not limited thereto.

Referring to FIG. 10, the light emitting device 150 may be inserted into the chamber 1300 filled with the fluid 1200. The fluid 1200 may be water such as ultrapure water, but is not limited thereto. The chamber may be called a water tank, container, vessel, etc.

After this, the substrate 200 may be placed on the chamber 1300. Depending on the embodiment, the substrate 200 may be input into the chamber 1300.

As shown in FIG. 9, a pair of assembly wirings 201 and 202 corresponding to each of the light emitting devices 150 to be assembled may be disposed on the substrate 200.

The assembly wirings 201 and 202 may be formed of transparent electrodes (ITO) or may contain a metal material with excellent electrical conductivity. For example, the assembly wirings 201 and 202 may be formed of at least one of titanium (Ti), chromium (Cr), nickel (Ni), aluminum (Al), platinum (Pt), gold (Au), tungsten (W), molybdenum (Mo), or an alloy thereof.

An electric field is formed in the assembly wiring (201, 202) by an externally supplied voltage, and a dielectrophoretic force may be formed between the assembly wiring (201, 202) by this electric field. The light emitting device 150 may be fixed to the assembly hole 203 on the substrate 200 by this dielectrophoretic force.

The gap between the assembly wirings 201 and 202 is formed to be smaller than the width of the light emitting device 150 and the width of the assembly hole 203, so that the assembly position of the light emitting device 150 using an electric field may be fixed more precisely.

An insulating layer 206 is formed on the assembly wirings 201 and 202 to protect the assembly wirings 201 and 202 from the fluid 1200 and prevent leakage of current flowing through the assembly wirings 201 and 202. The insulating layer 206 may be formed as a single layer or multilayer of an inorganic insulator such as silica or alumina or an organic insulator.

Additionally, the insulating layer 206 may include an insulating and flexible material such as polyimide, PEN, PET, etc., and may be integrated with the substrate 200 to form one substrate.

The insulating layer 206 may be an adhesive insulating layer or a conductive adhesive layer with conductivity. The insulating layer 206 is flexible and may enable flexible functions of the display device.

The insulating layer 206 has a partition, and the assembly hole 203 may be formed by this partition. For example, when forming the substrate 200, a portion of the insulating layer 206 is removed, so that each of the light emitting devices 150 may be assembled into the assembly hole 203 of the insulating layer 206.

An assembly hole 203 in which the light emitting devices 150 are coupled is formed in the substrate 200, and the surface where the assembly hole 203 is formed may be in contact with the fluid 1200. The assembly hole 203 may guide the exact assembly position of the light emitting device 150.

Meanwhile, the assembly hole 203 may have a shape and size corresponding to the shape of the light emitting device 150 to be assembled at the corresponding location. Accordingly, it is possible to prevent another light emitting device from being assembled in the assembly hole 203 or a plurality of light emitting devices from being assembled.

Referring again to FIG. 10, after the substrate 200 is disposed, the assembly device 1100 including a magnetic material may move along the substrate 200. For example, a magnet or electromagnet may be used as a magnetic material. The assembly device 1100 may move while in contact with the substrate 200 in order to maximize the area to which the magnetic field is applied within the fluid 1200. Depending on the embodiment, the assembly device 1100 may include a plurality of magnetic materials or a magnetic material of a size corresponding to that of the substrate 200. In this case, the moving distance of the assembly device 1100 may be limited to within a predetermined range.

By the magnetic field generated by the assembly device 1100, the light emitting device 150 in the chamber 1300 may move toward the assembly device 1100.

While moving toward the assembly device 1100, the light emitting device 150 may enter the assembly hole 203 and come into contact with the substrate 200.

At this time, by the electric field applied by the assembly wiring 201 and 202 formed on the substrate 200, the light emitting device 150 in contact with the substrate 200 may be prevented from being separated by movement of the assembly device 1100.

That is, by the self-assembly method using the electromagnetic field described above, since the time required to assemble each of the light emitting devices 150 on the substrate 200 may be drastically shortened, a large-area, high-pixel display may be implemented more quickly and economically.

A predetermined solder layer (not shown) is further formed between the light emitting device 150 assembled on the assembly hole 203 of the substrate 200 and the substrate 200, so that the bonding strength of the light emitting device 150 may be improved.

Afterwards, electrode wiring (not shown) is connected to the light emitting device 150 and power may be applied.

Next, although not shown, at least one insulating layer may be formed through a post-process. At least one insulating layer may be transparent resin or resin containing a reflective material or a scattering material.

Meanwhile, in the embodiment, the bonding layer provided on the lower side of the semiconductor light emitting device is surrounded by a barrier, even if the bonding layer is melted by thermal compression after the semiconductor light emitting device is self-assembled, the melted bonding layer may be prevented from escaping around the semiconductor light emitting device. Accordingly, the bonding force by which the semiconductor light emitting device is attached to the substrate may be improved. Additionally, the electrical contact resistance between the semiconductor light emitting device and the electrical wiring, that is, the second assembly wiring, may be minimized, thereby improving luminance. Additionally, since the semiconductor light emitting device is more firmly attached to the substrate, the semiconductor light emitting device does not come off, thereby preventing assembly defects and lighting defects.

Meanwhile, by forming a part of the first conductivity type semiconductor layer containing the first conductivity type dopant as a barrier, during thermal compression, heat is transferred to the bonding layer through the barrier, so that heat is evenly transferred to all areas of the bonding layer, allowing a smooth bonding process to be performed. Accordingly, bonding may be completed at the same time, shortening the bonding process time, and bonding defects due to different melting times may be prevented.

FIG. 11 is a cross-sectional view showing a display device according to an embodiment. FIG. 11 illustrates one sub-pixel among a plurality of sub-pixels, and an image may be displayed with a plurality of sub-pixels shown in FIG. 11.

Referring to FIG. 11, the display device 300 according to the embodiment may include a substrate 310, first and second assembly wirings 321 and 322, a second insulating layer 340, and a semiconductor light emitting device 150. The display device 300 according to an embodiment may include more components.

The substrate 310 may be a support member that supports components placed on the substrate 310 or a protection member that protects the components.

The first and second assembly wirings 321 and 322 may be disposed on the substrate 310. The first and second assembly wirings 321 and 322 may serve to assemble the semiconductor light emitting device 150 into the assembly hole 355 in a self-assembly method. That is, during self-assembly, an electric field is generated between the first assembly wiring 321 and the second assembly wiring 322 by the voltage supplied to the first and second assembly wiring 321 and 322, the moving semiconductor light emitting device 150 may be assembled in the assembly hole 355 by the assembly device (1100 in FIG. 10) by the dielectrophoretic force formed by this electric field.

According to the embodiment, the first assembly wiring 321 and the second assembly wiring 322 may be arranged in different layers. For example, the first assembly wiring 321 may be placed under the first insulating layer 330, and the second assembly wiring 322 may be placed on the first insulating layer 330. For example, the first assembly wiring 321 may be disposed between the substrate 310 and the first insulating layer 330. For example, the second assembly wiring 322 may be disposed on the first insulating layer 330, and its upper surface may be exposed to the outside, that is, to the assembly hole 355. A portion of the first insulating layer 330 and a portion of the second assembly wiring 322 may be exposed through the assembly hole 355. For example, the first insulating layer 330 may be made of an inorganic material or an organic material. For example, the first insulating layer 330 may be made of a material having a dielectric constant related to the dielectrophoretic force.

For example, the top surface of the first insulating layer 330 and the top surface of the second assembly wiring 322 may be located on the same horizontal line, but this is not limited. For example, when the semiconductor light emitting device 150 is assembled in the assembly hole 355, the lower side of the semiconductor light emitting device 150 may be in contact with a portion of the first insulating layer 330 and a portion of the second assembly wiring 322. In this case, the semiconductor light emitting device 150 and the second assembly wiring 322 may be electrically connected by the bonding layer 154_1 provided on the lower side of the semiconductor light emitting device 150. In this case, the second assembly wiring 322 may be a lower electrode wiring for supplying voltage to the lower side of the semiconductor light emitting device 150. As will be explained later, the electrode wiring 360 may be electrically connected to the upper side of the semiconductor light emitting device 150. Accordingly, the semiconductor light emitting device 150 may emit light by the voltage supplied to the second assembly wiring 322 and the electrode wiring 360. The second assembly wiring 322 may be called a first electrode wiring, and the electrode wiring 360 may be called an upper electrode wiring or a second electrode wiring.

The second insulating layer 340 is disposed on the substrate 310 and may have an assembly hole 355. The thickness of the second insulating layer 340 may be determined by considering the thickness of the semiconductor light emitting device 150. For example, the thickness of the second insulating layer 340 may be smaller than the thickness of the semiconductor light emitting device 150. Accordingly, the top of the semiconductor light emitting device 150 may be positioned higher than the top of the second insulating layer 340. That is, the upper side of the semiconductor light emitting device 150 may protrude upward from the top surface of the second insulating layer 340.

The size of the assembly hole 355 may be determined in consideration of the tolerance margin for forming the assembly hole 355 and the margin for easily assembling the semiconductor light emitting device 150 within the assembly hole 355. For example, the size of the assembly hole 355 may be larger than the size of the semiconductor light emitting device 150. For example, when the semiconductor light emitting device 150 is assembled in the center of the assembly hole 355, the distance between the outer side of the semiconductor light emitting device 150 and the inner side of the assembly hole 355 may be 2 μm or less, but is not limited to this.

For example, the assembly hole 355 may have a shape corresponding to the shape of the semiconductor light emitting device 150. For example, when the semiconductor light emitting device 150 is circular, the assembly hole 355 may also be circular. For example, when the semiconductor light emitting device 150 is rectangular, the assembly hole 355 may also be rectangular.

Meanwhile, the semiconductor light emitting device 150 may include a red semiconductor light emitting device that generates red light, a green semiconductor light emitting device that generates green light, and a blue semiconductor light emitting device that generates blue light.

For example, during self-assembly, the red semiconductor light emitting device, green semiconductor light emitting device, and blue semiconductor light emitting device distributed in the same chamber (1300 in FIG. 10) are moved simultaneously by the same assembly device 1100, may be assembled into assembly holes 355 of each corresponding sub-pixel (PX1, PX2, and PX3 in FIG. 6). When the size of the assembly hole 355 of each sub-pixel (PX1, PX2, and PX3 in FIG. 6) is the same, the red semiconductor light emitting device, the green semiconductor light emitting device, and the blue semiconductor light emitting device may not be assembled in the assembly hole 355 in which they are to be assembled, but may be assembled in another assembly hole 355. In order to solve this problem, the shapes of the red semiconductor light emitting device, green semiconductor light emitting device, and blue semiconductor light emitting device are changed, respectively. Assembly holes 355 may be formed to correspond to the different shapes of the red semiconductor light emitting device, green semiconductor light emitting device, and blue semiconductor light emitting device, respectively. Accordingly, since each of the red semiconductor light emitting device, green semiconductor light emitting device, and blue semiconductor light emitting device having different shapes is assembled in the assembly hole 355 corresponding to its shape, assembly defects may be prevented.

For example, the shape of the red semiconductor light emitting device is circular, the shape of the green semiconductor light emitting device may be a first oval with a first minor axis and a first major axis, and the shape of the blue semiconductor light emitting device may be a second elliptical shape with a second minor axis smaller than the first minor axis and a second major axis larger than the first major axis.

The semiconductor light emitting device 150 may be disposed in the assembly hole 355 to generate colored light. As described above, the semiconductor light emitting device 150 may include a red semiconductor light emitting device, a green semiconductor light emitting device, and a blue semiconductor light emitting device. For example, the red semiconductor light emitting device may be disposed in the first sub-pixel (PX1 in FIG. 6), the green semiconductor light emitting device may be disposed in the second sub-pixel PX2, and the blue semiconductor light emitting device may be disposed in the third sub-pixel PX3. Accordingly, a color image may be displayed using red light emitted from the first sub-pixel PX1, green light emitted from the second sub-pixel PX2, and blue light emitted from the third sub-pixel PX3.

The semiconductor light emitting device 150 of the embodiment may be a vertical semiconductor light emitting device, but this is not limited. In this case, after the semiconductor light emitting device 150 is assembled in the assembly hole 355, the first electrode 154 of the semiconductor light emitting device 150 may be electrically connected to the lower electrode wiring, and the second electrode 155 of the semiconductor light emitting device 150 may be electrically connected to the electrode wiring 360. Here, the lower electrode wire may be the second assembly wiring 322, but this is not limited. When thermal compression is performed after the semiconductor light emitting device 150 is assembled in the assembly hole 355, the first-first electrode 154_1 of the first electrode 154 of the semiconductor light emitting device 150, that is, the bonding layer, is melted by heat, and the semiconductor light emitting device 150 may be more strongly adhered to the substrate 310 by compression. The semiconductor light emitting device 150 may be attached to the substrate 310 via the molten bonding layer 154_1 and electrically connected to the second assembly wiring 322.

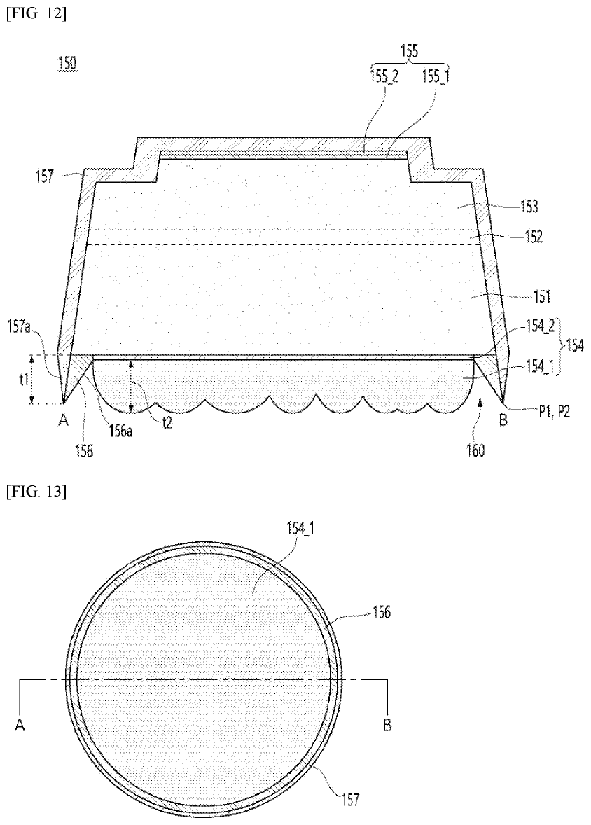

FIG. 12 is a cross-sectional view showing a semiconductor light emitting device according to the first embodiment, and FIG. 13 is a bottom view showing a semiconductor light emitting device according to the embodiment.

Referring to FIGS. 12 and 13, the semiconductor light emitting device 150 according to the first embodiment may include light emitting parts 151, 152, and 153, a first electrode 154, a second electrode 155, a passivation layer 157, and a barrier 156. The semiconductor light emitting device 150 according to the first embodiment may include more components than these.

The light emitting parts 151, 152, and 153 include a first conductivity type semiconductor layer 151, an active layer 152, and a second conductivity type semiconductor layer 153, but may include more components.

The first conductivity type semiconductor layer 151, the active layer 152, and the second conductivity type semiconductor layer 153 may be sequentially grown on a wafer (not shown) using deposition equipment such as MOCVD. Thereafter, the second conductivity type semiconductor layer 153, the active layer 152, and the first conductivity type semiconductor layer 151 may be etched along the vertical direction in that order using an etching process. Afterwards, the remaining area excluding a portion of the side of the first conductivity type semiconductor layer 151, that is, the passivation layer 157 is formed along the other part of the side of the first conductivity type semiconductor layer 151, the side of the active layer 152, and the side surface of the second conductivity type semiconductor layer 153, a semiconductor light emitting device 150 may be manufactured.

The first conductivity type semiconductor layer 151 may include a first conductivity type dopant, and the second conductivity type semiconductor layer 153 may include a second conductivity type dopant. For example, the first conductivity type dopant may be an n-type dopant such as silicon (Si), and the second conductivity type dopant may be a p-type dopant such as boron (B).

For example, the first conductivity type semiconductor layer 151 may generate electrons, and the second conductivity type semiconductor layer 153 may form holes. The active layer 152 generates light and may be referred to as a light emitting layer.

When the semiconductor light emitting device 150 of the embodiment is formed by mesa etching, the diameter may gradually increase from the top to the bottom of the semiconductor light emitting device 150.

The first electrode 154 may be disposed below the first conductivity type semiconductor layer 151.

The first electrode 154 may include at least one layer. For example, the first electrode 154 may include a first-first electrode 154_1 and a first-second electrode 154_2. For example, the first-first electrode 154_1 is a bonding layer for bonding the semiconductor light emitting device 150 to the substrate 310, and the first-second electrode 154_2 may be a bonding layer for bonding the bonding layer 154_1 to the lower side of the light emitting parts 151, 152, and 153, for example, the first conductivity type semiconductor layer 151.

For example, the bonding layer 154_1 may be made of indium (In), tin (Sn), etc. For example, indium (In) may have a melting point at 150 to 170 degrees, and tin may have a melting point at 230 to 250 degrees.

For example, the bonding layer 154_2 may be made of titanium (Ti), chromium (Cr), etc.

The second electrode 155 may be disposed on the second conductivity type semiconductor layer 153.

The second electrode 155 may include at least one or more layers. The second electrode 155 may include a second-first electrode 155_1 and a second-second electrode 155_2. For example, the second-first electrode 155_1 is disposed on the upper side of the semiconductor light emitting device 150, for example, on the second conductivity type semiconductor layer 153, the second-second electrode 155_2 may be disposed on the second-first electrode 155_1. As another example, the second-second electrode 155_2 may be disposed between the second conductivity type semiconductor layer 153 and the second-first electrode 155-1, but this is not limited.

For example, the second-first electrode 155_1 may be a transparent conductive layer, and the second-second electrode 155_2 may be a magnetic layer.

The second-first electrode 155_1 may be made of a transparent conductive material, such as ITO. The second-first electrode 155_1 may achieve a current spreading effect that allows the current generated by the voltage supplied from the electrode wiring 360 to spread evenly throughout the entire area of the second conductivity type semiconductor layer 153. That is, the current is spread evenly throughout the entire area of the second conductivity type semiconductor layer 153 by the second-first electrode 155_1, and holes are generated in the entire area of the second conductivity type semiconductor layer 153 increasing the amount of holes generated, the amount of light generated by recombination of holes and electrons in the active layer 152 may be increased, thereby improving light efficiency. An increase in light efficiency may lead to an improvement in luminance.

For example, the second-second electrode 155_2 may be a magnetic layer. The magnetic layer 155_2 may include nickel (Ni), cobalt (Co), iron (Fe), etc. The magnetic layer 155_2 may include SmCo, Gd-based, La-based, or Mn-based metal.

The magnetic layer 155_2 is magnetized by a magnetic material provided in the assembly device (FIG. 1100) during self-assembly, and serves to cause the semiconductor light emitting device 150 to exert an attractive force with the magnetic material. Accordingly, the semiconductor light emitting device 150 may move in the same manner as the magnetic material moves.

The second-second electrode 155_2 is formed to have a very thin thickness, on the order of nanometers (nm), so as not to interfere with the propagation of light of the semiconductor light emitting device 150, so that light may be transmitted.

During magnetic assembly, the semiconductor light emitting device 150 may be moved faster and more quickly according to the movement of the magnetic material, thereby shortening the process time and improving the assembly yield.

The passivation layer 157 may protect the light emitting parts 151, 152, and 153. For example, the passivation layer 157 may surround the light emitting parts 151, 152, and 153. For example, the passivation layer 157 may surround the second electrode 155. For example, the passivation layer 157 may be disposed along the side perimeter of the light emitting portions 151, 152, and 153 and may be disposed on the second electrode 155.

The passivation layer 157 is located on the lower side of the semiconductor light emitting device 150 so that the semiconductor light emitting device 150 does not turn over during self-assembly. That is, the lower surface of the first conductivity type semiconductor layer 151 may face the upper surface of the first insulating layer 330. That is, during self-assembly, the passivation layer 157 of the semiconductor light emitting device 150 may be positioned away from the first assembly wiring 321 and the second assembly wiring 322. Since the passivation layer 157 is not disposed on the lower side of the semiconductor light emitting device 150, the lower side of the semiconductor light emitting device 150 may be positioned to be close to the first assembly wiring 321 and the second assembly wiring 322. Therefore, during self-assembly, the lower side of the semiconductor light emitting device 150 is positioned facing the first insulating layer 330 and the upper side of the semiconductor light emitting device 150 is positioned toward the top, misalignment in which the semiconductor light emitting device 150 is assembled upside down may be prevented.

Meanwhile, the barrier 156 may be disposed along the perimeter of the bonding layer 154_1. The barrier 156 may be named a bulkhead, dam, guide, etc.

For example, the light emitting parts 151, 152, and 153 may include a first area and a second area surrounding the first area. For example, the first area may be a central area, and the second area may be an edge area surrounding the central area.

In these cases, the bonding layer 154_1 may be disposed under the first area of the light emitting parts 151, 152, and 153, and the barrier 156 may be placed under the second area of the light emitting parts 151, 152, and 153. For example, the bonding layer 154_1 may have a size corresponding to the size of the first area of the light emitting parts 151, 152, and 153, and the barrier 156 may have a size corresponding to the size of the second area.

For example, if the semiconductor light emitting device 150 is circular, the first area of the light emitting parts 151, 152, and 153 may have a circular shape, and the second area of the light emitting parts 151, 152, and 153 may have a ring shape (or donut shape) surrounding the first area having a circular shape. For example, the second area of the light emitting parts 151, 152, and 153 may have a closed loop, but this is not limited.

For example, the light emitting parts 151, 152, and 153 include a plurality of semiconductor layers, and the barrier 156 may be one of the plurality of semiconductor layers. That is, the barrier 156 may be grown on the wafer together with the first conductivity type semiconductor layer 151, the active layer 152, and the second conductivity type semiconductor layer 153 using deposition equipment.

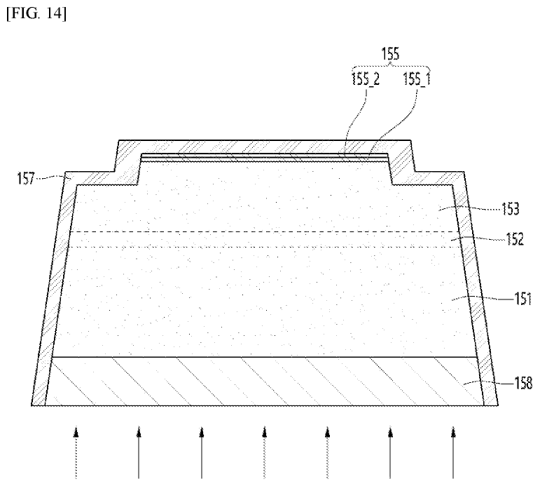

A method of manufacturing a semiconductor light emitting device including a barrier will be described with reference to FIGS. 14 to 16.

FIGS. 14 to 16 show a method of manufacturing a semiconductor light emitting device according to an embodiment.

As shown in FIG. 14, the third semiconductor layer 158, the first conductivity type semiconductor layer 151, the active layer 152, and the second conductivity type semiconductor layer 153 may be grown on the wafer using deposition equipment such as MOCVD. For example, the third semiconductor layer 158 may be an undoped semiconductor layer that does not contain a dopant, but this is not limited. Light emitting parts 151, 152, and 153 may be formed by the third semiconductor layer 158, the first conductivity type semiconductor layer 151, the active layer 152, and the second conductivity type semiconductor layer 153.

By performing a mesa etching process, the second conductivity type semiconductor layer 153, the active layer 152, the first conductivity type semiconductor layer 151, and the third semiconductor layer 158 may be sequentially etched.

The second electrode 155 including the second-first electrode 155_1 and the second-second electrode 155_2 may be formed on the second conductivity type semiconductor layer 153. Subsequently, a passivation layer 157 may be formed around the sides of the light emitting parts 151, 152, and 153 and on the second electrode 155.

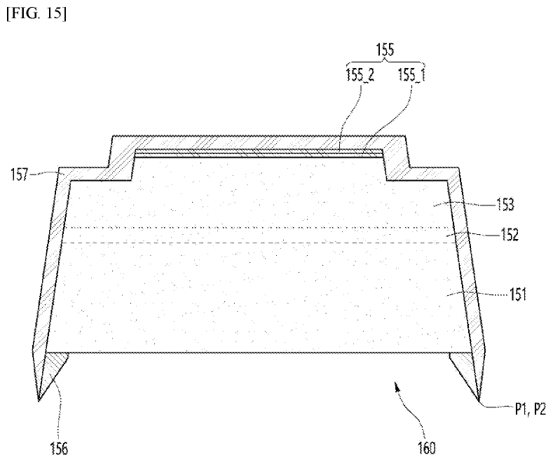

Next, the wafer may be separated from the light emitting parts 151, 152, and 153 using the LLO process. An etching process may be performed on the third semiconductor layer 158, which will be exposed to the outside due to separation of the wafer, to form a barrier 156, as shown in FIG. 15. During the etching process, the passivation layer 157 disposed around the side of the third semiconductor layer 158 acts as a mask, the etch rate of the third semiconductor layer 158 in contact with the passivation layer 157, that is, the etch rate of the third semiconductor layer 158 in the edge region, and the etch rate of the third semiconductor layer 158 in the center region may be different. That is, the etching of the third semiconductor layer 158 in the edge area may be hindered by the passivation layer 157, thereby slowing down the etching speed. On the other hand, the third semiconductor layer 158 in the central area is not disturbed by the passivation layer 157 and thus may have a normal etch rate.

The etching process for the third semiconductor layer 158 may be performed, for example, until the lower surface of the first conductivity type semiconductor layer 151 is exposed. For example, the etching process for the third semiconductor layer 158 may be performed until the third semiconductor layer 158 in the central area is removed.

Since the etching speed of the third semiconductor layer 158 in the edge area is slower than the etching speed of the third semiconductor layer 158 in the center area, even if the third semiconductor layer 158 in the center area is removed, a portion of the third semiconductor layer 158 in the edge area remains without being etched, and a barrier 156 may be formed.

The shape of the barrier 156 may vary depending on the thickness and material of the passivation layer 157.

In FIG. 14, the lower surface of the passivation layer and the lower surface of the third semiconductor layer 158 may be located on the same horizontal line. When the lower surface of the passivation layer 157 is higher than the lower surface of the third semiconductor layer 158, that is, when a portion of the side surface of the third semiconductor layer 158 is not covered by the passivation layer 157, since the passivation layer 157 does not function as a mask, the third semiconductor layer 158 in the edge area may also be removed and the barrier 156 may not be formed.

For example, the passivation layer 157 may be made of an inorganic material, such as silicon oxide series (SiOx), silicon nitride series (SiNx), etc.

If the thin film characteristics of the passivation layer 157 are poor or the thickness is too thick, the passivation layer 157 cannot be stably deposited on the side of the third semiconductor layer 158. In addition, a portion of the passivation layer 157 may be separated from the side of the third semiconductor layer 158 due to high power and temperature during the LLO process to separate the wafer.

Therefore, in order to solve this problem, it is necessary to optimize the thickness of the passivation layer 157. In an embodiment, the thickness of the passivation layer 157 is 50 nm to 200 nm, and is stably deposited on the side of the third semiconductor layer 158 and will not be separated from the side of the third semiconductor layer 158 even during the LLO process.

Meanwhile, as shown in FIG. 15, the third semiconductor layer 158 is partially removed, a groove 160 may be formed in the portion where the third semiconductor layer 158 has been removed, and a barrier 156 may be formed in the portion where the third semiconductor layer 158 remains.

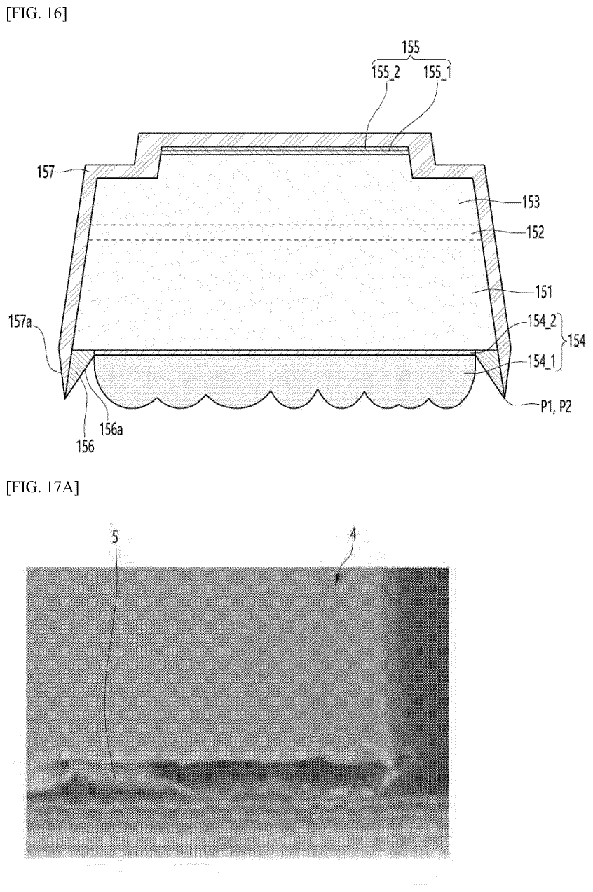

As shown in FIG. 16, the first electrode 154 may be formed in the groove 160. First, the first-second electrode 154_2, i.e., a bonding layer, may be formed, and the first-first electrode 154_1, i.e., a bonding layer, may be formed via the first-second electrode 154_2. That is, the bonding layer 154_1 may be bonded to the first conductivity type semiconductor layer 151 by the bonding layer 154_2. The adhesion layer 154_2 and the bonding layer 154_1 may be formed in the groove 160.

When the bonding layer 154_1 is directly bonded to the first conductivity type semiconductor layer 151, the bonding layer 154_2 may be omitted.

Referring again to FIG. 12, the thickness t2 of the bonding layer 154_1 may be greater than the thickness t1 of the barrier 156. Since the bonding layer 154_1 melts during heat compression, its volume may be reduced. Therefore, in order to stably bond the semiconductor light emitting device 150 to the substrate 310, the thickness t2 of the bonding layer 154_1 may be greater than the thickness t1 of the barrier 156. In this case, even if the bonding layer 154_1 melts and the volume decreases due to heat compression, since the thickness t2 of the bonding layer 154_1 is greater than the thickness t1 of the barrier 156, the lower surface of the bonding layer 154_1 protrudes further downward than the lower surface of the partition when viewed from the side of the final product. The lower surface of the bonding layer 154_1 may be in contact with the upper surface of the substrate 310, for example, the second assembly wiring 322. At this time, the bonding layer 154_1 may contact the second assembly wiring 322 face-to-face.

The thickness t2 of the bonding layer 154_1 may be the same as the thickness t1 of the barrier 156. In this case, not only the bonding layer 154_1 but also the barrier 156 may contact the second assembly wiring 322.

Meanwhile, the lower side of the passivation layer 157 and the lower side of the barrier 156 may have peak points (P1 and P2) due to an etching process for forming the barrier 156. For example, the peak point P1 on the lower side of the barrier 156 and the peak point P2 on the lower side of the passivation layer 157 may be located on the same horizontal line.

The barrier 156 may have an inclined surface 156a on the inside. The inclined surface 156a may be formed by the difference in etch rate between the center area and the edge area of the third semiconductor layer (158 in FIG. 14), with the passivation layer 157 acting as a mask. For example, as the difference in etch rate between the center region and the edge region of the third semiconductor layer (158 in FIG. 14) increases, the inclination angle of the inclined surface 156a may increase, but this is not limited.

The inclined surface 156a may have a straight side, but may also have another side, such as a round side.

During the etching process for the third semiconductor layer (158 in FIG. 14), not only the third semiconductor layer 158 but also the passivation layer 157 may be etched, although the etching speed is slow. Accordingly, an inclined surface 157a may be formed outward from the peak point P1 on the lower side of the passivation layer 157.

Meanwhile, referring again to FIG. 11, the display device 300 according to the embodiment may include a first insulating layer 330, a third insulating layer 350, and an electrode wire 360.

The first insulating layer 330 may be disposed on the substrate 310.

In the embodiment, the first assembly wiring 321 and the second assembly wiring 322 may be arranged in different layers, but this is not limited. For example, the first assembly wiring 321 is disposed between the substrate 310 and the first insulating layer 330, the second assembly wiring 322 is disposed on the first insulating layer 330 and may be exposed to the outside through the assembly hole 355. The second assembly wiring 322 may be a lower electrode wiring for supplying voltage to the semiconductor light emitting device 150. That is, after the semiconductor light emitting device 150 is assembled in the assembly hole 355, the second assembly wiring 322 exposed to the assembly hole 355 may be electrically connected to the lower side of the semiconductor light emitting device 150, for example, using the bonding layer 154_1.

The second insulating layer 340 may be disposed on the second insulating layer 340. The second insulating layer 340 may be disposed on the semiconductor light emitting device 150. The second insulating layer 340 may be a planarization layer to easily form the electrode wiring 360 or other layers. Accordingly, the top surface of the second insulating layer 340 may have a flat surface.

The first insulating layer 330, the second insulating layer 340, and the second insulating layer 340 may be formed of an organic material or an inorganic material. The first insulating layer 330, the second insulating layer 340, and the second insulating layer 340 may be made of the same material or the same material as each other, but this is not limited.

The electrode wire 360 may be disposed on the second insulating layer 340 and electrically connected to the semiconductor light emitting device 150 through the second insulating layer 340. For example, the electrode wiring 360 may be electrically connected to the second electrode 155 through the second insulating layer 340 and the passivation layer 157 of the semiconductor light emitting device 150.

Accordingly, light may be emitted from the semiconductor light emitting device 150 by the voltage supplied by the second assembly wiring and the electrode wiring 360.

Descriptions omitted above may be easily understood from FIG. 9 and the description related thereto.

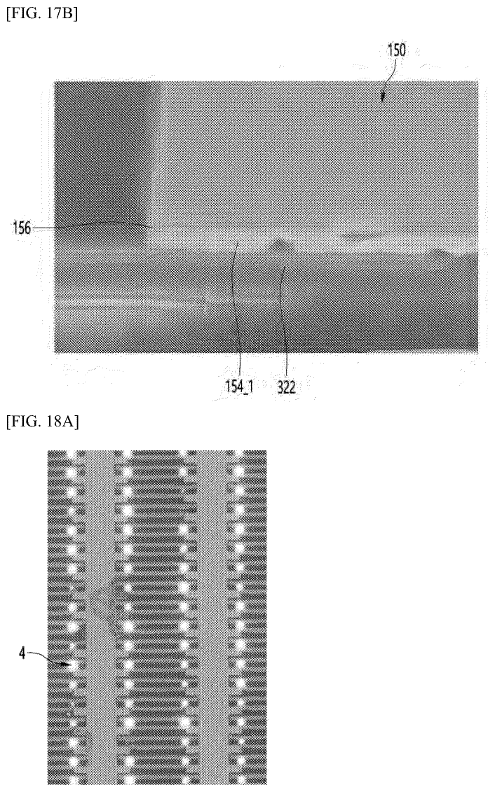

FIGS. 17A and 17B are photographic images showing bonding layers of the prior art and embodiments.

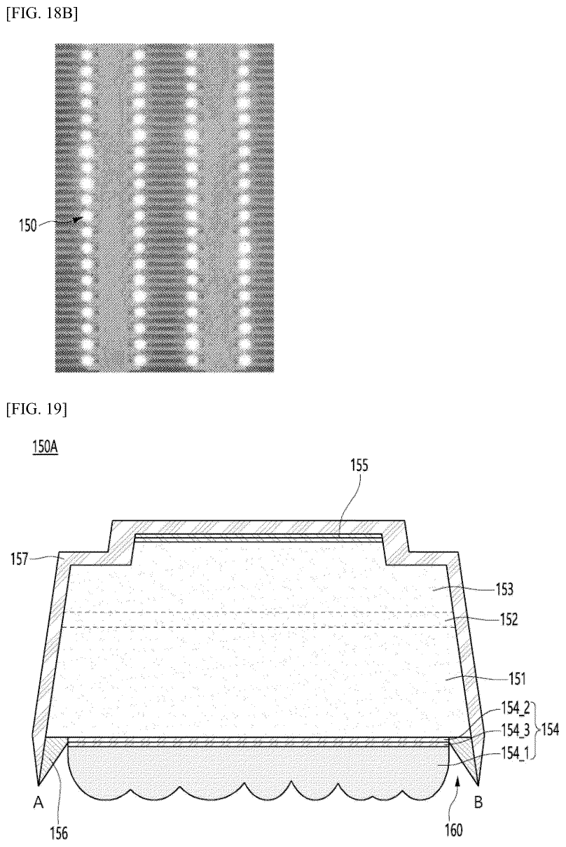

As shown in FIG. 17A, in the related art, no member is provided to confine the bonding material 5 during heat compression, so most of the bonding material 5 escapes around the semiconductor light emitting device 4, almost no bonding material 5 remains between the semiconductor light emitting device 150 and the substrate, resulting in poor electrical connection between the semiconductor light emitting device 4 and the electrical wiring. Accordingly, as shown in FIG. 18A, it may be seen that many semiconductor light emitting devices 4 do not emit light or have lighting defects in which light with low luminance is emitted.

As shown in FIG. 17B, in the embodiment, a barrier 156 is provided to confine the bonding layer 154_1 during heat compression, most of the bonding layer 154_1 remains between the semiconductor light emitting device 150 and the substrate 310, allowing electrical connection between the semiconductor light emitting device 150 and the lower electrode wiring 322. Especially, the contact area between the semiconductor light emitting device 150 and the lower electrode wiring 322 is maximized to minimize electrical resistance, and the voltage supply from the lower electrode wiring 322 to the semiconductor light emitting device 150 may be smoothly supplied, thereby improving brightness. As shown in FIG. 18B, the plurality of semiconductor light emitting devices 150 emit light with desired luminance without lighting defects, and in particular, uniform luminance is obtained between each sub-pixel (PX1, PX2, and PX3 in FIG. 6), thereby improving image quality.

According to the embodiment, the barrier 156 is disposed around the bonding layer 154_1 provided on the lower side of the semiconductor light emitting device 150, even if the bonding layer 154_1 is melted and pressed during thermal compression, the melted layer 154_1 does not escape to the periphery of the semiconductor light emitting device 150, that is, to the edge of the assembly hole 355, due to the barrier 156, or only a portion of it may escape. Therefore, compared to the related art, since there is almost no bonding layer 154_1 that escapes from the periphery of the semiconductor light emitting device 150, electrical short circuit defects with the electrode wiring 360 caused by bonding material that escapes from the periphery of the semiconductor light emitting device 150 may be prevented.

In addition, there is almost no bonding layer 154_1 missing around the semiconductor light emitting device 150, since most of the bonding layer is located within the barrier 156, that is, between the semiconductor light emitting device 150 and the substrate 310, the bonding layer is provided with a predetermined thickness, for example, at least the thickness of the barrier 156 or greater, so that it is possible to prevent electrical connection failure between the semiconductor light emitting device 150 and the lower electrode wiring, that is, the second assembly wiring 322.

In addition, almost no bonding layer 154_1 escapes from the periphery of the semiconductor light emitting device 150, and most of the bonding layer 154_1 is within the barrier 156. That is, since the bonding layer 154_1 is located between the semiconductor light emitting device 150 and the substrate 310 and is provided with a predetermined thickness, for example, at least the thickness of the barrier 156 or greater, the semiconductor light emitting device 150 is firmly attached to the substrate 310, for example, the first insulating layer 330 and the second assembly electrode, thereby preventing the semiconductor light emitting device 150 from being separated, thereby improving product reliability.

Meanwhile, according to the embodiment, the bonding layer 154_1 made of metal is disposed on the lower side of the semiconductor light emitting device 150 with a thickness greater than the thickness of the barrier 156, this means that the volume or amount of the bonding layer 154_1 has increased. Typically, dielectrophoretic force is greatly affected by metallic materials. Accordingly, the dielectrophoretic force increases due to the increased bonding layer, and the semiconductor light emitting device 150 is pulled more strongly into the assembly hole 355 by this increased dielectrophoretic force, thereby increasing the assembly rate and reducing assembly defects.

In addition, when the barrier 156 of the semiconductor light emitting device 150 disposed in each sub-pixel (PX1, PX2, and PX3 in FIG. 6) is the same during thermal compression, the bonding layer 154_1 melted by the thermal compression is confined by the barrier 156, and the volume or amount of the bonding layer 154_1 remaining between the semiconductor light emitting device 150 and the substrate 310 in each sub-pixel PX1, PX2, PX3 may be the same or similar.

In addition, during thermal compression, heat is not only transferred to the upper side of the bonding layer (154_1) through the central area of the light emitting portions (151, 152, and 153), the heat is transferred to the side of the bonding layer 154_1 through the barrier 156 located corresponding to the edge area of the light emitting portions 151, 152, and 153, since the entire area of the bonding layer 154_1 may be melted at the same time, a smooth bonding process may be performed. In other words, bonding may be completed at the same time, shortening the bonding process time, and bonding defects due to different melting times may be prevented.

FIG. 19 is a cross-sectional view showing a semiconductor light emitting device according to the second embodiment.

The second embodiment is the same as the first embodiment except that the magnetic layer 154_3 is included in the first electrode 154. In the second embodiment, components having the same structure, shape, and/or function as those of the first embodiment are assigned the same reference numerals and detailed descriptions are omitted.

Referring to FIG. 19, the semiconductor light emitting device 150A according to the second embodiment may include light emitting parts 151, 152, and 153, a first electrode 154, a second electrode 155, a passivation layer 157, and a barrier 156. The semiconductor light emitting device 150A according to the second embodiment may include more components.

The first electrode 154 may include at least one layer. For example, the first electrode 154 may include a first-first electrode 154_1, a first-second electrode 154_2, and a first-third electrode 154_3. For example, the first-third electrode may be disposed between the first-first electrode 154_1 and the first-second electrode 154_2. For example, the first-third electrode may be disposed between the first-second electrode 154_2 and the first conductivity type semiconductor layer 151.

The electrode 154_1 may be a bonding layer, the first-second electrode 154_2 may be a bonding layer, and the first-third electrode 154_3 may be a magnetic layer. For example, the bonding layer 154_1 may be made of indium (In), tin (Sn), or the like. For example, the bonding layer 154_2 may be made of titanium (Ti), chromium (Cr), or the like. The magnetic layer 154_3 may include nickel (Ni), cobalt (Co), iron (Fe), etc. The magnetic layer 154_3 may include SmCo, Gd-based, La-based, or Mn-based metal.

In the first embodiment, the magnetic layer 155_2 is included in the second electrode 155, but in the second embodiment, the magnetic layer 154_3 may be included in the first electrode 154. During magnetic assembly, the semiconductor light emitting device 150A may be moved faster and more quickly according to the movement of the magnetic material, thereby shortening the process time and improving the assembly yield.

The electrode 155 may be a transparent conductive layer, but there is no limitation thereto.

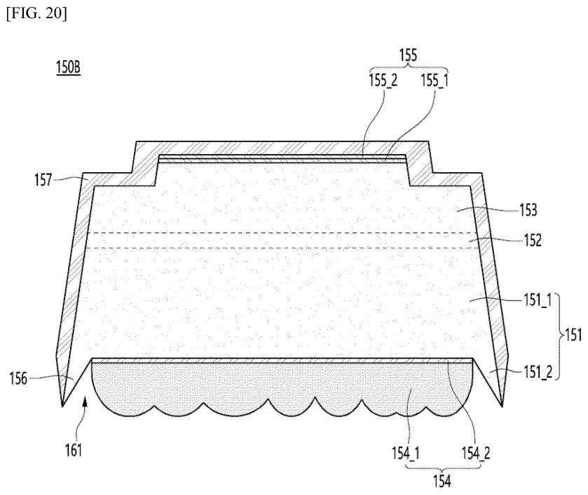

FIG. 20 is a cross-sectional view showing a semiconductor light emitting device according to the third embodiment.

The embodiment is the same as the first and/or second embodiment except that a part of the first conductivity type semiconductor layer 151 is formed as a barrier 156. In the third embodiment, components having the same structure, shape, and/or function as those of the first and/or second embodiments are assigned the same reference numerals and detailed descriptions are omitted.

Referring to FIG. 20, the semiconductor light emitting device 150B according to the third embodiment may include light emitting parts 151, 152, and 153, a first electrode 154, a second electrode 155, a passivation layer (157) and a barrier (156). The semiconductor light emitting device 150B according to the third embodiment may include more components.

The barrier 156 may be a part of the first conductivity type semiconductor layer 151. That is, by partially etching the lower surface of the first conductivity type semiconductor layer 151, the barrier 156 may be formed as part of the first conductivity type semiconductor layer 151.

For example, as shown in FIG. 14, after the third semiconductor layer 158, the first conductivity type semiconductor layer 151, the active layer 152, and the second conductivity type semiconductor layer 153 are grown, mesa etching may be performed. Next, after the wafer is separated, the third semiconductor layer 158 may be removed through an etching process. After the lower surface of the first conductivity type semiconductor layer 151 is attached to another substrate and the second electrode 155 is formed on the second conductivity type semiconductor layer 153, the passivation layer 157 may be formed. Next, after another substrate is separated, an etching process is performed on the first conductivity type semiconductor layer 151 using the passivation layer 157 as a mask, the central region of the first conductivity type semiconductor layer 151 is removed to form the groove 161, and the edge region of the first conductivity type semiconductor layer 151 remains to form the barrier 156.

Meanwhile, the first conductivity type semiconductor layer 151 includes a first-first conductivity type semiconductor layer 151_1 below the active layer 152, and a first-second conductivity type semiconductor layer 151_2 below the first-first conductivity type semiconductor layer.

The first-second conductivity type semiconductor layer may have a groove 161 whose center area is empty and a barrier 156 located at the edge area. That is, the groove 161 and the barrier 156 may be formed by partially etching the first-second conductivity type semiconductor layer. For example, the central region of the first-second conductivity type semiconductor layer is removed to form the groove 161, and the edge region of the first-second conductive type semiconductor layer is not completely removed, so some remaining portion may be formed as a barrier 156.

The barrier 156 may extend downward from the edge region of the first-first conductivity type semiconductor layer.

The bonding layer 154_1 may be formed in the groove 161 using the bonding layer 154_2.

Since the barrier 156 contains a first conductivity type dopant, when the barrier 156 is electrically connected to the lower electrode wire, that is, the second assembly wiring 322, through a bonding process after assembly in the assembly hole 355, since the voltage of the lower electrode wiring is supplied not only through the bonding layer 154_1 but also through the barrier 156, a smoother voltage supply is possible and luminance may be improved.

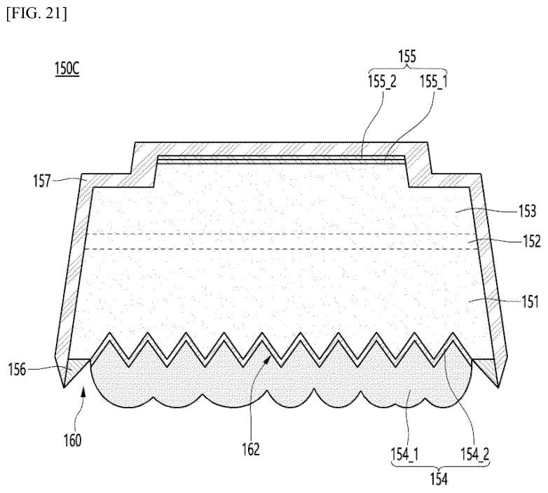

FIG. 21 is a cross-sectional view showing a semiconductor light emitting device according to the fourth embodiment.

The embodiment is the same as the first or second embodiment except for the unevenness 162. In the fourth embodiment, components having the same structure, shape, and/or function as those of the first and/or second embodiments are assigned the same reference numerals and detailed descriptions are omitted.

Referring to FIG. 21, the semiconductor light emitting device 150C according to the fourth embodiment may include light emitting parts 151, 152, and 153, a first electrode 154, a second electrode 155, a passivation layer 157, and a barrier 156. The semiconductor light emitting device 150C according to the fourth embodiment may include more components.

The unevenness 162 may be provided on the lower side of the light emitting portions 151, 152, and 153. The grooves 160 and the unevenness 162 may be formed together when forming the barrier 156.

As shown in FIG. 14, an etching process may be performed on the third semiconductor layer 158. The etching process may be continuously performed until the grooves 160 and the unevenness 162 are formed. First, the central region of the third semiconductor layer 158 may be removed to expose the lower surface of the first conductivity type semiconductor layer 151. Subsequently, by additionally performing an etching process, unevenness 162 may be formed on the lower surface of the first conductivity type semiconductor layer 151.

In the embodiment, the etching process is performed until the unevenness 162 is formed, so that the etching process time in the fourth embodiment is longer than the etching process time in the first and/or second embodiment, since the edge area of the third semiconductor layer 158 is further etched with the increased time, the inclined surface 156a of the barrier 156 may have a larger inclined angle compared to the first and/or second embodiments, but is not limited to this.

Since light traveling downward by the semiconductor light emitting device 150C is reflected and/scattered by the unevenness 162, light efficiency may be increased and luminance may be improved.

In addition, when forming the barrier 156, the grooves 160 and the unevenness 162 are formed together, so there is no need to form separate unevenness, so the structure is simple, the process time is shortened, and the manufacturing cost may be reduced.

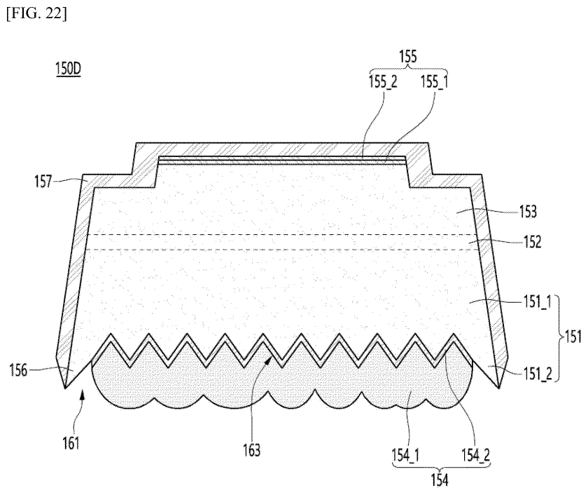

FIG. 22 is a cross-sectional view showing a semiconductor light emitting device according to the fifth embodiment.

The embodiment is the same as the third embodiment except for the unevenness 163. Additionally, the fifth embodiment is the same as the first, second and/or fourth embodiments except that a portion of the first conductivity type semiconductor layer 151 is formed as a barrier 156. In the fifth embodiment, components having the same structure, shape, and/or function as those of the first to fourth embodiments are assigned the same reference numerals and detailed descriptions are omitted.

Referring to FIG. 22, the semiconductor light emitting device 150D according to the fifth embodiment includes light emitting parts 151, 152, and 153, a first electrode 154, a second electrode 155, a passivation layer 157 and a barrier 156. The semiconductor light emitting device 150D according to the fifth embodiment may include more components.

The unevenness 163 may be provided on the lower side of the light emitting portions 151, 152, and 153. The grooves 161 and the unevenness 163 may be formed together when forming the barrier 156.

As described in the third embodiment, the third semiconductor layer 158 may be removed through a series of processes to expose the first conductivity type semiconductor layer 151 to the outside. Next, an etching process may be performed on the first conductivity type semiconductor layer 151 using the passivation layer 157 as a mask. Accordingly, the central region of the first conductivity type semiconductor layer 151 is removed to form the groove 161, and the edge region of the first conductivity type semiconductor layer 151 is not removed to form the barrier 156. Next, by additionally performing an etching process, unevenness 163 may be formed in the central area of the first conductivity type semiconductor layer 151. The unevenness 163 may be formed under etching process conditions that are different from the etching process conditions for forming the grooves 161 so that the unevenness 163 are formed more clearly, but is not limited to this.

In the fifth embodiment, the etching process is performed until the unevenness 163 is formed, so that the etching process time in the fifth embodiment is increased compared to the etching process time in the third embodiment, since the edge area of the first conductivity type semiconductor layer 151 is further etched by the increased time, the inclined surface 156a of the barrier 156 may have a larger inclination angle compared to the third embodiment, but is not limited to this.

Since light traveling downward by the semiconductor light emitting device 150D is reflected and/scattered by the unevenness 163, light efficiency may be increased and luminance may be improved.

In addition, when forming the barrier 156, the grooves 161 and the unevenness 163 are formed together, so there is no need to form separate unevenness, so the structure is simple, the process time is shortened, and the manufacturing cost may be reduced.

The above detailed description should not be construed as restrictive in any respect and should be considered illustrative. The scope of the embodiments should be determined by reasonable interpretation of the appended claims, and all changes within the equivalent scope of the embodiments are included in the scope of the embodiments.

### INDUSTRIAL APPLICABILITY

The embodiment may be adopted in the field of displays that display images or information.

The embodiment may be adopted in the field of displays that display images or information using semiconductor light emitting devices. The semiconductor light emitting device may be a micro-level semiconductor light emitting device or a nano-level semiconductor light emitting device.

1. A semiconductor light emitting device comprising:
a light emitting part;
a first electrode including a bonding layer below the light emitting part;
a barrier around the bonding layer;
a second electrode on the light emitting part;
a passivation layer to surround the light emitting part and the second electrode; and
a third semiconductor layer below the first conductivity type semiconductor layer. wherein a material of the barrier comprises a part of the third semiconductor layer.

2. The semiconductor light emitting device according to claim 1, wherein the light emitting part comprises a first area and a second area to surround the first area,
wherein the bonding layer is disposed below the first region, and
wherein the barrier is disposed below the second area.

3. The semiconductor light emitting device according to claim 1, wherein the light emitting part comprises a plurality of semiconductor layers, and wherein the barrier is one semiconductor layer among the plurality of semiconductor layers.

4. The semiconductor light emitting device according to claim 1, wherein the light emitting part comprises a first conductivity type semiconductor layer, an active layer on the first conductivity type semiconductor layer, and a second conductivity type semiconductor layer on the active layer, and wherein the barrier is disposed along an edge area of the active layer.

5. (canceled)

6. The semiconductor light emitting device according to claim 1, wherein the third semiconductor layer comprises a groove corresponding to the first region and is disposed to correspond to the second region in the first conductivity type semiconductor layer, and
wherein the bonding layer is disposed in the groove.

7. The semiconductor light emitting device according to claim 6, wherein the lower surface of the first conductivity type semiconductor layer corresponding to the groove comprises a unevenness, and wherein the bonding layer is disposed on the unevenness.

8. A semiconductor light emitting device comprising:
a light emitting part;
a first electrode including a bonding layer below the light emitting part;
a barrier around the bonding layer;
a second electrode on the light emitting part; and
a passivation layer to surround the light emitting part and the second electrode;
wherein a material of the barrier comprises a part of the first conductivity type semiconductor layer.

9. The semiconductor light emitting device according to claim 8, wherein the first conductivity type semiconductor layer comprises a first-first conductivity type semiconductor layer below the active layer and a first-second conductivity type semiconductor having a groove corresponding to the first region and extending downwardly from the first-first conductivity type semiconductor layer corresponding to the second region, and
wherein the bonding layer is disposed in the groove.

10. The semiconductor light emitting device according to claim 9, wherein the barrier is the first-second conductivity type semiconductor layer.

11. The semiconductor light emitting device according to claim 9, wherein the lower surface of the first-first conductivity type semiconductor layer corresponding to the groove has unevenness, and wherein the bonding layer is disposed on the unevenness.

12. The semiconductor light emitting device according to claim 1, wherein a thickness of the bonding layer is greater than a thickness of the barrier.

13. The semiconductor light emitting device according to claim 1, wherein the barrier comprises an inwardly inclined surface.

14. The semiconductor light emitting device according to claim 13, wherein the passivation layer in contact with outer surface of the barrier has an outward slope.

15. The semiconductor light emitting device according to claim 14, wherein a peak point below the barrier and a peak point below the passivation layer are located on a same horizontal line.

16. The semiconductor light emitting device according to claim 1, comprising a vertical type semiconductor light emitting device.

17. A display device comprising:
a substrate:
a first assembly line and a second assembly wiring on the substrate:
a second insulating layer disposed on the substrate and having an assembly hole; and
a semiconductor light emitting device in the assembly hole,
wherein the semiconductor light emitting device comprises a light emitting part, a first electrode including a bonding layer below the light emitting part, a barrier around the bonding layer, a second electrode on the light emitting part, and a passivation layer to surround the light emitting part and the second electrode, and
wherein the one of the first assembly wiring and second assembly wiring is electrically connected to the first electrode.

18. The display device according to claim 17, wherein a thickness of the bonding layer is greater than a thickness of the barrier.

19. The display device according to claim 17, further comprising a first insulating layer below the second insulating layer, a first assembly wiring under the first insulating layer, and a second assembly wiring on the first insulating layer, and
wherein the bonding layer is in contact with the second assembly wiring.

20. The display device according to claim 19, wherein the barrier is in contact with the second assembly wiring,
wherein the bonding layer is in contact with the second assembly wiring face to face, and
wherein the lower side of the barrier comprises a peak point that contacts the second assembly wiring.

21. The display device according to claim 17, wherein a material of the barrier comprises a part of the light emitting part.
